(19) United States
(12) Patent Application Publication
(10) Pub. No.: US 2024/0079391 A1
(43) Pub. Date: Mar. 7, 2024

(54) Die Structures and Methods of Forming the Same

(71) Applicant: Taiwan Semiconductor Mqanufacturing Co., Ltd., Hsinchu (KR)

(72) Inventors: Chia-Hao Hsu, Hsinchu (TW); Jian-Wei Hong, Hsinchu (TW); Kuo-Chiang Ting, Hsinchu (TW); Sung-Feng Yeh, Hsinchu (TW)

(21) Appl. No.: 18/152,451

(22) Filed: Jan. 10, 2023

Related U.S. Application Data
(60) Provisional application No. 63/427,265, filed on Nov. 22, 2022.
(60) Provisional application No. 63/374,794, filed on Sep. 7, 2022.

(51) Int. Cl. H01L 25/10; H01L 21/56; H01L 23/00; H01L 23/24; H01L 23/31; H01L 25/00; H10B 80/00

(52) U.S. Cl. CPC H01L 25/105; H01L 21/568; H01L 23/24; H01L 23/3135; H01L 24/05; H01L 24/08; H01L 24/80; H01L 25/50; H10B 80/00; H01L 23/538; H01L 2224/0557; H01L 2224/05572; H01L 2224/05624; H01L 2224/05639; H01L 2224/05644; H01L 2224/05647; H01L 2224/05684; H01L 2224/08145; H01L 2224/08237; H01L 2224/09181

(57) ABSTRACT

In an embodiment, a device includes: a first integrated circuit die comprising a semiconductor substrate and a first through-substrate via; a gap-fill dielectric around the first integrated circuit die, a surface of the gap-fill dielectric being substantially coplanar with an inactive surface of the semiconductor substrate and with a surface of the first through-substrate via; a dielectric layer on the surface of the gap-fill dielectric and the inactive surface of the semiconductor substrate; a first bond pad extending through the dielectric layer to contact the surface of the first through-substrate via, a width of the first bond pad being less than a width of the first through-substrate via; and a second integrated circuit die comprising a die connector bonded to the first bond pad.

### PRIORITY CLAIM AND CROSS-REFERENCE

This application claims the benefit of U.S. Provisional Application No. 63/427,265, filed on Nov. 22, 2022 and U.S. Provisional Application No. 63/374,794, filed on Sep. 7, 2022, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2-12 are cross-sectional views of intermediate stages in the manufacturing of a die structure, in accordance with some embodiments.

FIGS. 13-19 are cross-sectional views of die structures, in accordance with some embodiments.

FIGS. 20-26 are cross-sectional views of intermediate stages in the manufacturing of a die structure, in accordance with some embodiments.

FIGS. 27-33 are cross-sectional views of die structures, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a die structure is formed by bonding integrated circuit dies in a face-to-back manner. Bond pads are formed in a dielectric layer between layers of the integrated circuit dies. The bond pads are connected to through-substrate vias (TSVs) of the lower integrated circuit dies and to die connectors of the upper integrated circuit dies. The bond pads have a lesser width than the through-substrate vias, which helps reduce the risk of the bond pads contacting the semiconductor substrates of the lower integrated circuit dies, even if a process for recessing the semiconductor substrates is omitted. Shorting of the devices of the semiconductor substrates may thus be avoided.

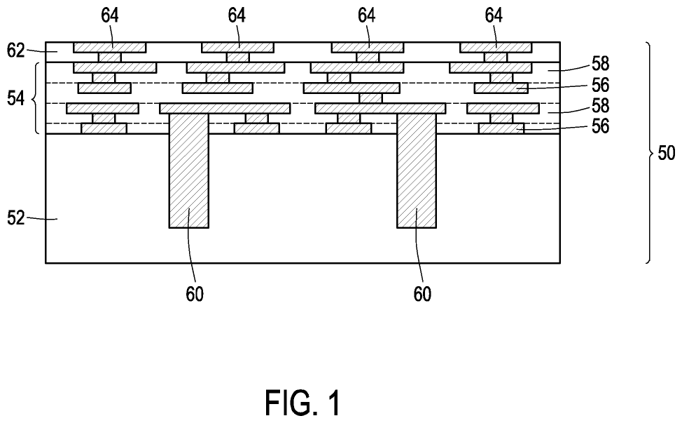

FIG. 1 is a cross-sectional view of an integrated circuit die 50. The integrated circuit die 50 will be bonded to other dies in subsequent processing to form a die structure. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front-side, and an inactive surface (e.g., the surface facing downwards in FIG. 1), sometimes called a back-side.

Devices (not separately illustrated) are disposed at the active surface of the semiconductor substrate 52. The devices may be active devices (e.g., transistors, diodes, etc.), capacitors, resistors, etc. An interconnect structure 54 is disposed over the active surface of the semiconductor substrate 52. The interconnect structure 54 interconnects the devices of the semiconductor substrate 52 to form an integrated circuit. The interconnect structure 54 may be formed of, for example, metallization patterns 56 in dielectric layers 58. The dielectric layers 58 may be, e.g., low-k dielectric layers 58. The metallization patterns 56 include metal lines and vias, which may be formed in the dielectric layers 58 by a damascene process, such as a single damascene process, a dual damascene process, or the like. The metallization patterns 56 may be formed of a suitable conductive material, such as copper, tungsten, aluminum, silver, gold, a combination thereof, or the like, which can be formed by, for example, plating or the like. The metallization patterns 56 are electrically coupled to the devices of the semiconductor substrate 52.

Optionally, conductive vias 60 extend into the interconnect structure 54 and/or the semiconductor substrate 52. The conductive vias 60 are electrically coupled to the metallization patterns 56 of the interconnect structure 54. As an example to form the conductive vias 60, recesses can be formed in the interconnect structure 54 and/or the semiconductor substrate 52 by, for example, etching, milling, laser techniques, a combination thereof, or the like. A thin barrier layer may be conformally deposited in the recesses, such as by chemical vapor deposition (CVD), atomic layer deposition (ALD), physical vapor deposition (PVD), thermal oxidation, a combination thereof, or the like. The barrier layer may be formed from an oxide, a nitride, combinations thereof, or the like. A conductive material may be deposited over the barrier layer and in the recesses. The conductive material may be formed by an electro-chemical plating process, CVD, ALD, PVD, a combination thereof, or the like. Examples of conductive materials include copper, tungsten, aluminum, silver, gold, a combination thereof, or the like. Excess conductive material and barrier layer is removed from a surface of the interconnect structure 54 or the semiconductor substrate 52 by, for example, a chemical-mechanical polish (CMP). The remaining portions of the barrier layer and conductive material in the recesses form the conductive vias 60. After their initial formation, the conductive vias 60 may be buried in the semiconductor substrate 52. The semiconductor substrate 52 may be thinned in subsequent processing to expose the conductive vias 60 at the inactive surface of the semiconductor substrate 52. After the exposure process, the conductive vias 60 are through-substrate vias (TSVs), such as through-silicon vias, that extend through the semiconductor substrate 52.

In this embodiment, the conductive vias 60 are formed by a via-middle process, such that the conductive vias 60 extend through a portion of the interconnect structure 54 (e.g., a subset of the dielectric layers 58) and extend into the semiconductor substrate 52. The conductive vias 60 formed by a via-middle process are connected to a middle metallization pattern 56 of the interconnect structure 54. In another embodiment, the conductive vias 60 are formed by a via-first process, such that the conductive vias 60 extend into the semiconductor substrate 52 but not the interconnect structure 54. The conductive vias 60 formed by a via-first process are connected to a lower metallization pattern 56 of the interconnect structure 54. In yet another embodiment, the conductive vias 60 are formed by a via-last process, such that the conductive vias 60 extend through an entirety of the interconnect structure 54 (e.g., each of the dielectric layers 58) and extend into the semiconductor substrate 52. The conductive vias 60 formed by a via-last process are connected to an upper metallization pattern 56 of the interconnect structure 54.

A dielectric layer 62 is over the interconnect structure 54, at the front-side of the integrated circuit die 50. The dielectric layer 62 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a benzocyclobutene (BCB) based polymer, or the like; a combination thereof; or the like. The dielectric layer 62 may be formed, for example, by CVD, spin coating, lamination, or the like. In some embodiments, the dielectric layer 62 is formed of TEOS-based silicon oxide. Optionally, one or more passivation layer(s) (not separately illustrated) are disposed between the dielectric layer 62 and the interconnect structure 54.

Die connectors 64 extend through the dielectric layer 62. The die connectors 64 may include conductive pillars, pads, or the like, to which external connections can be made. In some embodiments, the die connectors 64 include bond pads at the front-side of the integrated circuit die 50, and include bond pad vias that connect the bond pads to the upper metallization pattern 56 of the interconnect structure 54. In such embodiments, the die connectors 64 (including the bond pads and the bond pad vias) may be formed by a damascene process, such as a single damascene process, a dual damascene process, or the like. The die connectors 64 may be formed of a suitable conductive material, such as copper, tungsten, aluminum, silver, gold, a combination thereof, or the like, which can be formed by, for example, plating or the like.

Optionally, solder regions (not separately illustrated) may be formed on the die connectors 64 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 64. Chip probe testing may be performed on the integrated circuit die 50 to ascertain whether the integrated circuit die 50 is a known good die (KGD). Thus, only integrated circuit dies 50, which are KGDs, undergo subsequent processing, and dies which fail the chip probe testing are not subsequently processed. After testing, the solder regions may be removed. In some embodiments, a planarization process such as a chemical mechanical polish (CMP), an etch-back process, combinations thereof, or the like is utilized.

In some embodiments, the integrated circuit die 50 is a stacked device that includes multiple semiconductor substrates 52. For example, the integrated circuit die 50 may be a memory device that includes multiple memory dies such as a hybrid memory cube (HMC) device, a high bandwidth memory (HBM) device, or the like. In such embodiments, the integrated circuit die 50 includes multiple semiconductor substrates 52 interconnected by TSVs. Each of the semiconductor substrates 52 may (or may not) have a separate interconnect structure 54.

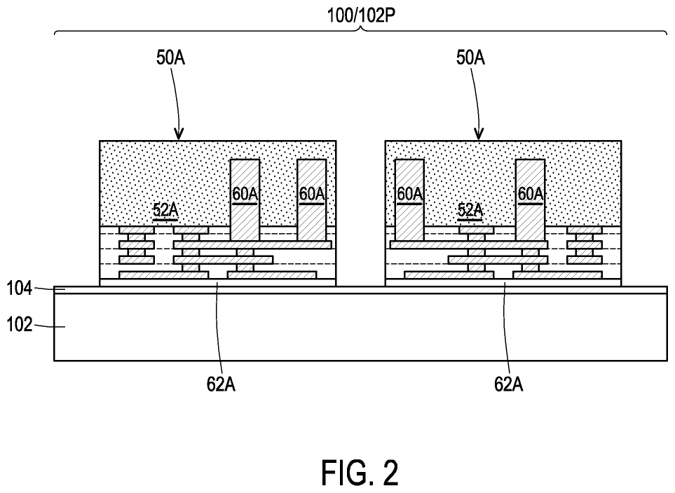

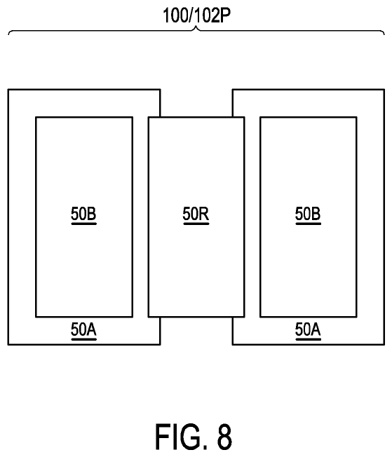

FIGS. 2-12 are views of intermediate stages in the manufacturing of a die structure 100, in accordance with some embodiments. FIGS. 2, 3, 4, 5, 6, 7, 9, 10, 11, and 12 are cross-sectional views. FIG. 8 is a top-down view. The die structure 100 is a stack of integrated circuit dies 50 (including first integrated circuit dies 50A and second integrated circuit dies 50B). The die structure 100 is formed by bonding the integrated circuit dies 50 together in a device region 102D. The device region 102D will be singulated to form the die structure 100. Processing of one device region 102D is illustrated, but it should be appreciated that any number of device regions 102D can be simultaneously processed to form any number of the die structures 100.

The die structure 100 is a component that may be subsequently packaged to form an integrated circuit package. The integrated circuit dies 50 of the die structure 100 may be heterogeneous dies. Packaging the die structure 100 in lieu of packaging the dies individually may allow heterogeneous dies to be integrated with a smaller footprint. The die structure 100 may be a system-on-integrated-chips (SoIC) device, although other types of devices may be formed.

In FIG. 2, a carrier substrate 102 is provided. The carrier substrate 102 may be a glass carrier substrate, a ceramic carrier substrate, or the like. The carrier substrate 102 may be a wafer, such that multiple packages can be formed on the carrier substrate 102 simultaneously.

First integrated circuit dies 50A are attached to a carrier substrate 102 in a face-down manner, such that the front-sides of first integrated circuit dies 50A are attached to the carrier substrate 102. In the illustrated embodiment, two first integrated circuit dies 50A are attached in the device region 102D, although any desired quantity of first integrated circuit dies 50A may be attached in the device region 102D. In some embodiments, the first integrated circuit dies 50A are logic dies (previously described).

The first integrated circuit dies 50A each have a similar structure to that described for FIG. 1, except the first integrated circuit dies 50A do not include the die connectors 64 (previously described for FIG. 1). Die connectors for the first integrated circuit dies 50A will be subsequently formed after other integrated circuit dies are attached to the first integrated circuit dies 50A.

The first integrated circuit dies 50A may be attached to the carrier substrate 102 by placing the first integrated circuit dies 50A on the carrier substrate 102, and then bonding the first integrated circuit dies 50A to the carrier substrate 102. The first integrated circuit dies 50A may be placed by, e.g., a pick-and-place process. The bonding process may include fusion bonding, dielectric bonding, or the like. As an example of the bonding process, the first integrated circuit dies 50A may be boned to the carrier substrate 102 with one or more bonding layer(s) 104. The bonding layer(s) 104 are on front-sides of the first integrated circuit dies 50A and/or on a surface of the carrier substrate 102. In some embodiments, the bonding layer(s) 104 include a release layer, such as an epoxy-based thermal-release material, which loses its adhesive property when heated, such as a light-to-heat-conversion (LTHC) release coating; an ultra-violet (UV) glue, which loses its adhesive property when exposed to UV light; or the like. In some embodiments, the bonding layer(s) 104 include an adhesive, such as a suitable epoxy, a die attach film (DAF), or the like. In some embodiments, the bonding layer(s) 104 include an oxide layer such as a layer of silicon oxide. The bonding layer(s) 104 may be applied to front-sides of the first integrated circuit dies 50A, may be applied over the surface of the carrier substrate 102, and/or the like. For example, the bonding layer(s) 104 may be applied to the front-sides of the first integrated circuit dies 50A before singulating to separate the first integrated circuit dies 50A.

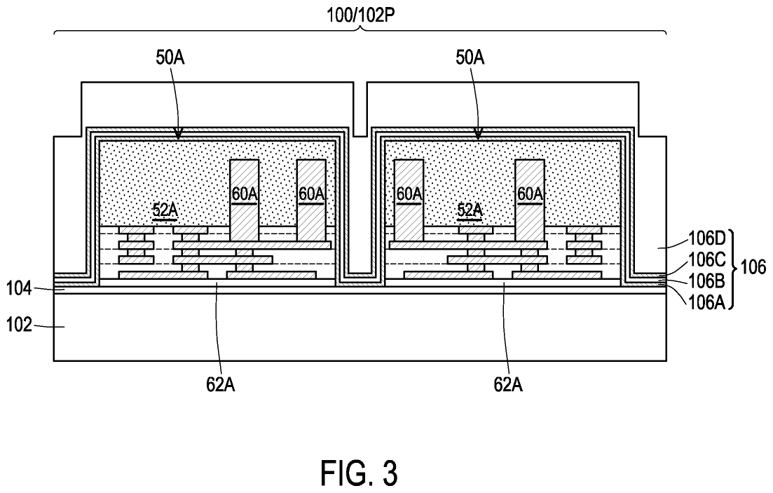

In FIG. 3, a gap-fill dielectric 106 is formed around the first integrated circuit dies 50A. The gap-fill dielectric 106 is a dielectric filler (or dielectric feature) that fills the gaps between the first integrated circuit dies 50A. The gap-fill dielectric 106 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like. Initially, the gap-fill dielectric 106 may be formed on the first integrated circuit dies 50A, such that the gap-fill dielectric 106 buries or covers the first integrated circuit dies 50A. Accordingly, the top surface of the gap-fill dielectric 106 may initially be above the back-sides of the first integrated circuit dies 50A.

In some embodiments, the gap-fill dielectric 106 is multi-layered including one or more liner layer(s) and a main layer. In this embodiment, the gap-fill dielectric 106 includes a first liner 106A, a second liner 106B, a third liner 106C, and a main filler 106D. The gap-fill dielectric 106 may have a nitride-oxide-nitride-oxide (NONO) structure, in which the first liner 106A and the third liner 106C are formed of nitrides (previously described), and in which the second liner 106B and the main filler 106D are formed of oxides (previously described). For example, the first liner 106A and the third liner 106C may be nitride liners formed of silicon nitride, the second liner 106B may be an oxide liner formed of silicon oxide, and the main filler 106D may be an oxide filler formed of silicon oxide. Utilizing an NONO structure may reduce the risk of damaging the first integrated circuit dies 50A when forming the gap-fill dielectric 106. For example, cracking of the gap-fill dielectric 106 along the edges of the first integrated circuit dies 50A may be avoided when an NONO structure is formed.

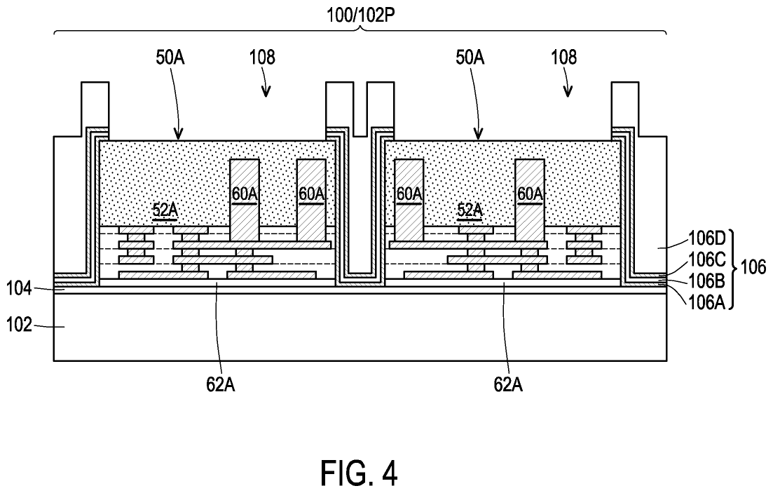

In FIG. 4, portions of the gap-fill dielectric 106 above the first integrated circuit dies 50A may optionally be removed to form openings 108. The portions of the gap-fill dielectric 106 above the first integrated circuit dies 50A may be removed by suitable photolithography and etching techniques. The openings 108 may expose the back-sides of the first integrated circuit dies 50A. Removing portions of the gap-fill dielectric 106 by etching may reduce pattern loading effects during a subsequent process for planarizing the gap-fill dielectric 106.

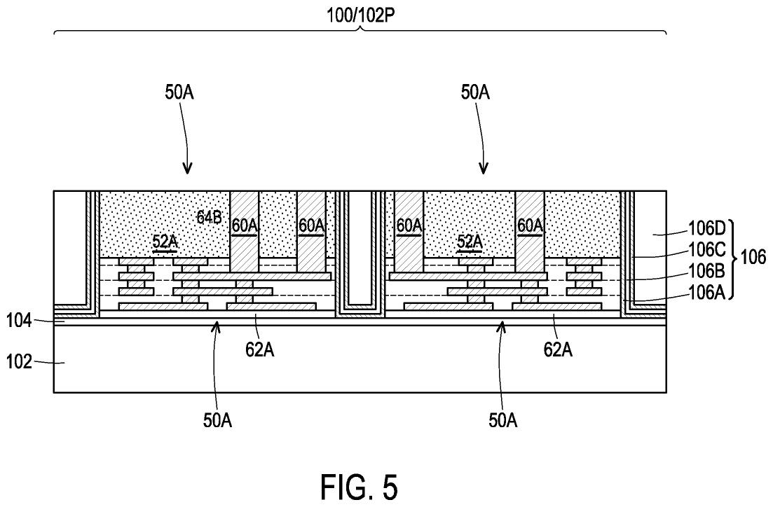

In FIG. 5, a removal process is performed to level surfaces of the gap-fill dielectric 106 with the back-sides of the first integrated circuit dies 50A (e.g., the inactive surfaces of the semiconductor substrates 52A). The remaining portions of the gap-fill dielectric 106 above the first integrated circuit dies 50A are removed. In some embodiments, a planarization process such as a chemical mechanical polish (CMP), an etch-back process, combinations thereof, or the like is utilized.

Additionally, the semiconductor substrates 52A are thinned to expose the conductive vias 60A of the first integrated circuit dies 50A. Portions of the gap-fill dielectric 106 along sidewalls of the semiconductor substrates 52A may also be removed by the thinning process. The thinning process may be, for example, a chemical-mechanical polish (CMP), a grinding process, an etch-back process, the like, or a combination thereof, which is performed at the back-sides of the first integrated circuit dies 50A. The planarization process may be performed until surfaces of the gap-fill dielectric 106 and the first integrated circuit dies 50A (including surfaces of the semiconductor substrates 52A and the conductive vias 60A) are substantially coplanar (within process variations). The thinning process for the semiconductor substrates 52A may (or may not) be different than the removal process for the gap-fill dielectric 106. After the exposure process, the conductive vias 60A are through-substrate vias (TSVs) that extend through the semiconductor substrates 52A.

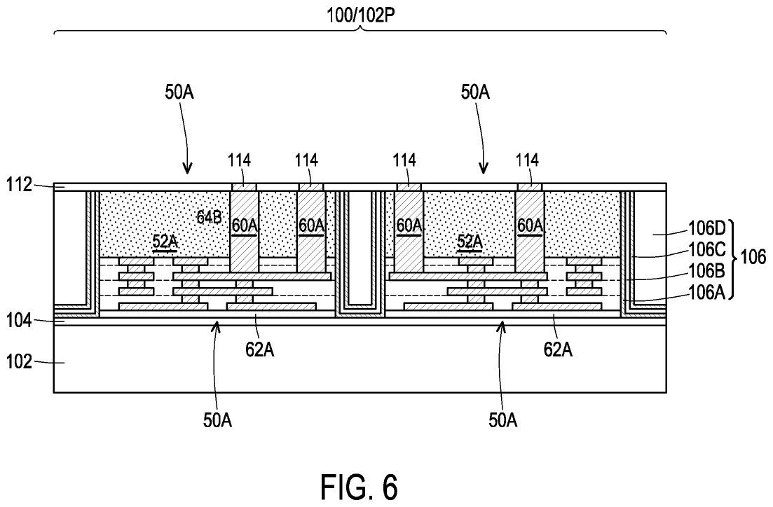

In FIG. 6, a dielectric layer 112 is formed on the coplanar top surfaces of the gap-fill dielectric 106 and the first integrated circuit dies 50A. The dielectric layer 112 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layer 112 may be formed of a low-k dielectric material having a k-value lower than about 3.0. The dielectric layer 112 may be formed of an extra-low-k (ELK) dielectric material having a k-value of less than 2.5.

Bond pads 114 are formed in the dielectric layer 112. The bond pads 114 extend through the dielectric layer 112 to contact the conductive vias 60A. The bond pads 114 may be formed by a damascene process, specifically, a single damascene process. As an example to form the bond pads 114, the dielectric layer 112 is patterned utilizing photolithography and etching techniques to form openings corresponding to the desired pattern of the bond pads 114. The openings may then be filled with a conductive material. Suitable conductive materials include copper, silver, gold, tungsten, aluminum, combinations thereof, or the like, which may be formed by electroplating or the like. A removal process may be performed to remove excess conductive material from a surface of the dielectric layer 112. In some embodiments, a planarization process such as a chemical mechanical polish (CMP), an etch-back process, combinations thereof, or the like is utilized. The remaining conductive material forms the bond pads 114 in the openings.

Each bond pad 114 is smaller (e.g., narrower) than the underlying conductive via 60A. More specifically, the critical dimension (e.g., width) of the bond pads 114 is less than the critical dimension (e.g., width) of the conductive vias 60A. In some embodiments, the critical dimension of the bond pads 114 is in the range of 0.5 μm to 5 μm and the critical dimension of the conductive vias 60A is in the range of 1 μm to 10 μm. Forming the bond pads 114 smaller than the conductive vias 60A helps reduce the risk of the bond pads 114 contacting the semiconductor substrates 52A. As a result, the bond pads 114 are spaced apart from the semiconductor substrates 52A by dielectric materials. Shorting of the devices of the semiconductor substrates 52A may thus be avoided.

The bond pads 114 are formed on the conductive vias 60A in lieu of recessing the semiconductor substrates 52A so that the conductive vias 60A protrude from the inactive surface of the semiconductor substrates 52A. Vertical connections to overlying integrated circuit dies may thus be achieved without recessing the semiconductor substrates 52A. When the gap-fill dielectric 106 has a nitride-oxide-nitride-oxide structure, omitting the recessing of the semiconductor substrates 52A may avoid etching of the first liner 106A and the third liner 106C (e.g., nitrides), thereby reducing pin hole defects in the die structure 100. Reducing pin hole defects can improve the yield and reliability of the die structure 100. For example, reducing pin hole defects can improve the strength of bonds with subsequently bonded dies.

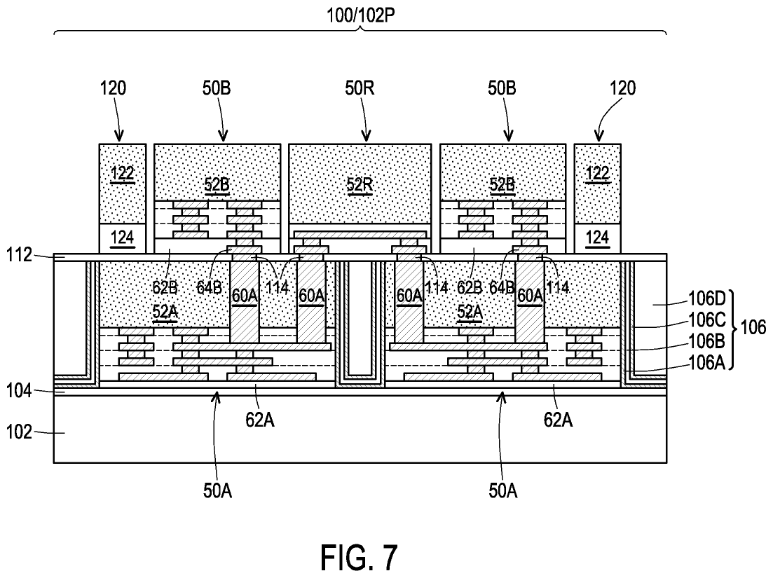

In FIG. 7, second integrated circuit dies 50B are attached to the dielectric layer 112 and the bond pads 114, such that the front-sides of the second integrated circuit dies 50B face the back-sides of the first integrated circuit dies 50A. In the illustrated embodiment, one second integrated circuit die 50B is attached above each first integrated circuit die 50A, although any desired quantity of second integrated circuit dies 50B may be attached above each first integrated circuit die 50A. In some embodiments, the second integrated circuit dies 50B are memory dies, power management dies, or the like (previously described). The function of the second integrated circuit dies 50B may (or may not) be different than the function of the first integrated circuit dies 50A. The first integrated circuit dies 50A and the second integrated circuit dies 50B may be formed in processes of a same technology node, or may be formed in processes of different technology nodes. For example, the first integrated circuit dies 50A may be of a more advanced process node than the second integrated circuit dies 50B. The first integrated circuit dies 50A may be wider than the second integrated circuit dies 50B.

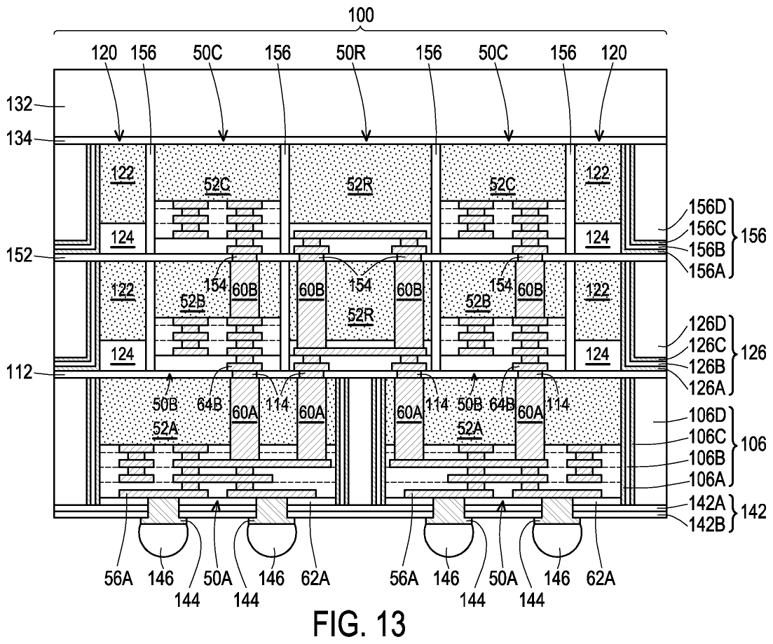

The second integrated circuit dies 50B each have a similar structure to that described for FIG. 1, except the second integrated circuit dies 50B do not include the conductive vias 60. The die structure 100 will include two layers of integrated circuit dies 50, and the conductive vias 60 are excluded from the second integrated circuit dies 50B because the second integrated circuit dies 50B are the upper layer of integrated circuit dies 50 in the die structure 100. In other embodiments (subsequently described for FIG. 13), the die structure 100 includes more than two layers of integrated circuit dies 50, such as three layers of integrated circuit dies 50, and the conductive vias 60 may be formed in other layers of integrated circuit dies 50 besides the upper layer of integrated circuit dies 50.

The second integrated circuit dies 50B may be attached to the dielectric layer 112 and the bond pads 114 by placing the second integrated circuit dies 50B on the dielectric layer 112 and the bond pads 114, and then bonding the second integrated circuit dies 50B to the dielectric layer 112 and the bond pads 114. The second integrated circuit dies 50B may be placed by, e.g., a pick-and-place process. The bonding process may include fusion bonding, dielectric bonding, metal bonding, a combination thereof (e.g., a combination of dielectric-to-dielectric bonding and metal-to-metal bonding), or the like. As an example of the bonding process, the second integrated circuit dies 50B may be directly bonded to the dielectric layer 112 and the bond pads 114 by a combination of dielectric-to-dielectric bonding and metal-to-metal bonding. The dielectric layers 62B of the second integrated circuit dies 50B are directly bonded to the dielectric layer 112 through dielectric-to-dielectric bonding, without using any adhesive material (e.g., die attach film). The die connectors 64B of the second integrated circuit dies 50B are directly bonded to the bond pads 114 through metal-to-metal bonding, without using any eutectic material (e.g., solder). The bonding may include a pre-bonding and an annealing. During the pre-bonding, a small pressing force is applied to press the second integrated circuit dies 50B against the dielectric layer 112. The pre-bonding is performed at a low temperature, such as about room temperature, such as a temperature in the range of 15° C. to 30° C., and after the pre-bonding, the dielectric layers 62B are bonded to the dielectric layer 112. The bonding strength is then improved in a subsequent annealing process, in which the dielectric layer 112, the bond pads 114, the dielectric layers 62B, and the die connectors 64B are annealed. After the annealing, direct bonds such as fusion bonds are formed, bonding the dielectric layer 112 to the dielectric layers 62B. For example, the bonds can be covalent bonds between the material of the dielectric layer 112 and the material of the dielectric layers 62B. The bond pads 114 contact the die connectors 64B. The bond pads 114 and the die connectors 64B may be in physical contact after the pre-bonding, or may expand to be brought into physical contact during the annealing. Further, during the annealing, the material of the bond pads 114 and the die connectors 64B (e.g., copper) intermingles, so that metal-to-metal bonds are also formed. Hence, the resulting bonds between the second integrated circuit dies 50B, the dielectric layer 112, and the bond pads 114 include both dielectric-to-dielectric bonds and metal-to-metal bonds.

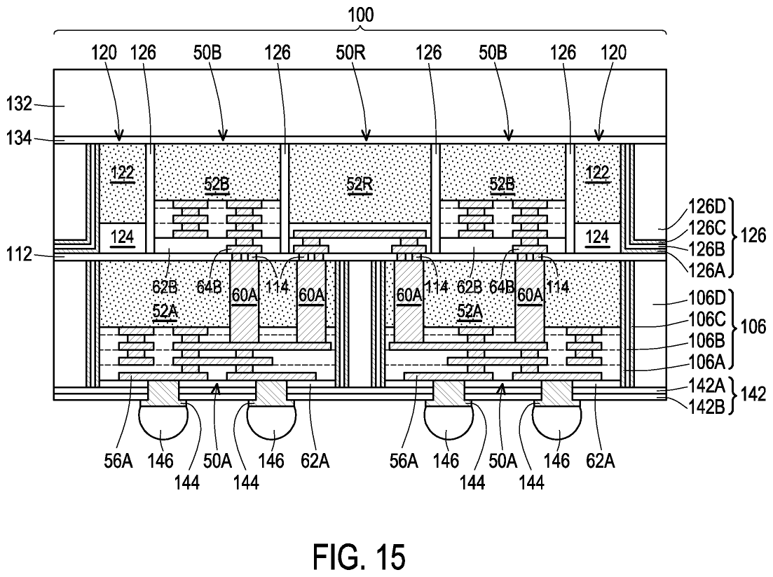

The bond pads 114 are disposed between the conductive vias 60A and the die connectors 64B. In this embodiment, the bond pads 114 contact the conductive vias 60A with a one-to-one correspondence and also contact the die connectors 64B with a one-to-one correspondence. Each bond pad 114 is smaller (e.g., narrower) than the underlying conductive via 60A, and may be smaller than the overlying die connector 64B. A width of each bond pad 114 may be greater than half a width of the underlying conductive via 60A and of the overlying die connector 64B. In another embodiment (subsequently described for FIG. 15), the bond pads 114 contact the conductive vias 60A with a one-to-many correspondence and also contact the die connectors 64B with a one-to-many correspondence.

Optionally, a bridge die 50R is attached to the dielectric layer 112 and the bond pads 114, such that the front-side of the bridge die 50R faces the back-sides of the first integrated circuit dies 50A. The bridge die 50R overlaps more than one of the first integrated circuit dies 50A. In the illustrated embodiment, one bridge die 50R is attached in the device region 102D, although any desired quantity of bridge dies 50R may be attached in the device region 102D. The bridge die 50R may be a local silicon interconnect (LSI), a large scale integration package, an interposer die, or the like.

The bridge die 50R may have a similar structure to that described for FIG. 1, except the bridge die 50R does not include conductive vias 60. Further, the bridge die 50R may (or may not) be substantially free of any active or passive devices. As such, the semiconductor substrate 52R of the bridge die 50R may be undoped. The bridge die 50R is electrically coupled to the first integrated circuit dies 50A, and may be utilized to interconnect the devices of the first integrated circuit dies 50A. The bridge die 50R may be attached to the dielectric layer 112 and the bond pads 114 in a similar manner as previously described for the second integrated circuit dies 50B. In some embodiments, the bridge die 50R is bonded to the dielectric layer 112 and the bond pads 114 by the same bonding process as the second integrated circuit dies 50B.

Optionally, dummy semiconductor features 120 are attached to the dielectric layer 112. Any desired quantity of dummy semiconductor features 120 may be attached to the dielectric layer 112, such that each dummy semiconductor feature 120 overlaps at least one first integrated circuit die 50A. In some embodiments, the dummy semiconductor features 120 are disposed around the second integrated circuit dies 50B in the device region 102D. The outer sidewalls of each dummy semiconductor feature 120 may (or may not) be aligned with the outer sidewalls of a respective first integrated circuit die 50A. When the first integrated circuit dies 50A are wider than the second integrated circuit dies 50B, including the dummy semiconductor features 120 can help reduce the size of gaps between the second integrated circuit dies 50B, thereby improving structural reliability of the die structure 100.

The dummy semiconductor features 120 are substantially free of any active or passive devices. The dummy semiconductor features 120 may each include a semiconductor substrate 122 and a dielectric layer 124. The semiconductor substrate 122 may be formed of a similar material as the semiconductor substrate 52 (previously described for FIG. 1), except the semiconductor substrate 122 may be undoped. The dielectric layer 124 may be formed of a similar material as the dielectric layer 62 (previously described for FIG. 1).

The dummy semiconductor features 120 may be attached to the dielectric layer 112 by placing the dummy semiconductor features 120 on the dielectric layer 112, and then bonding the dummy semiconductor features 120 to the dielectric layer 112. The dummy semiconductor features 120 may be placed by, e.g., a pick-and-place process. The bonding process may include fusion bonding, dielectric bonding, or the like. For example, The dielectric layers 124 of the dummy semiconductor features 120 may be directly bonded to the dielectric layer 112 through dielectric-to-dielectric bonding, without using any adhesive material (e.g., die attach film). The bonding may include a pre-bonding and an annealing, in a similar manner as the bonding of the second integrated circuit dies 50B to the dielectric layer 112. In some embodiments, the dummy semiconductor features 120 are bonded to the dielectric layer 112 by the same bonding process as the second integrated circuit dies 50B.

FIG. 8 is a schematic top-down view of a layout of the first integrated circuit dies 50A, the second integrated circuit dies 50B, and the bridge die 50R. In this embodiment, each second integrated circuit die 50B is disposed above a corresponding first integrated circuit die 50A, and is confined within the boundaries of that first integrated circuit die 50A. The bridge die 50R is disposed above multiple first integrated circuit dies 50A, and crosses the boundaries of those first integrated circuit dies 50A.

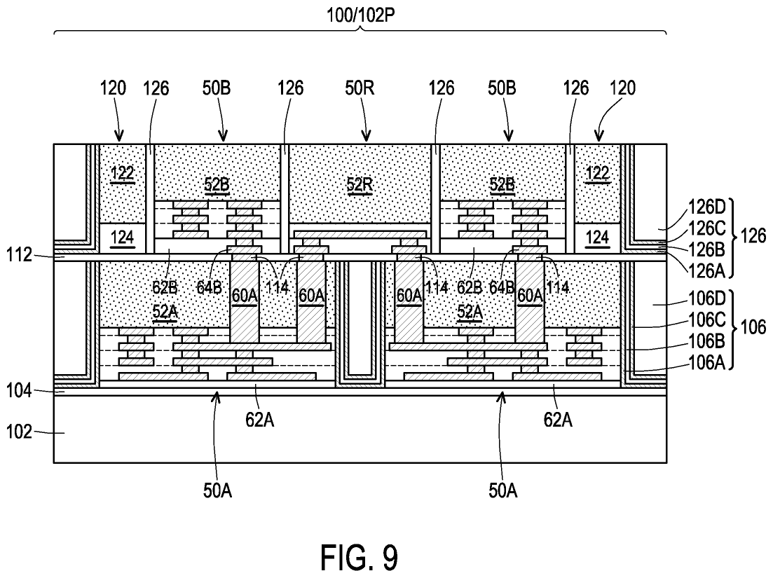

In FIG. 9, a gap-fill dielectric 126 is formed around the second integrated circuit dies 50B, the bridge die 50R (if present), and the dummy semiconductor features 120 (if present). The gap-fill dielectric 126 is a dielectric filler (or dielectric feature) that fills the gaps between the dummy semiconductor features 120, the bridge die 50R, and/or the second integrated circuit dies 50B. The gap-fill dielectric 126 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like.

In some embodiments, the gap-fill dielectric 126 is multi-layered including one or more liner layer(s) and a main layer. In this embodiment, the gap-fill dielectric 126 includes a first liner 126A, a second liner 126B, a third liner 126C, and a main filler 126D. The gap-fill dielectric 126 may have a nitride-oxide-nitride-oxide (NONO) structure, in which the first liner 126A and the third liner 126C are formed of nitrides (previously described), and in which the second liner 126B and the main filler 126D are formed of oxides (previously described). For example, the first liner 126A and the third liner 126C may be nitride liners formed of silicon nitride, the second liner 126B may be an oxide liner formed of silicon oxide, and the main filler 126D may be an oxide filler formed of silicon oxide. Utilizing an NONO structure may reduce the risk of damaging the second integrated circuit dies 50B when forming the gap-fill dielectric 126. For example, cracking of the gap-fill dielectric 126 along the edges of the second integrated circuit dies 50B may be avoided when an NONO structure is formed. The NONO structure is not separately illustrated in the gaps between the dummy semiconductor features 120, the bridge die 50R, and/or the second integrated circuit dies 50B.

The gap-fill dielectric 126 may be processed in a similar manner as the gap-fill dielectric 106. For example, the gap-fill dielectric 126 may initially be formed on the second integrated circuit dies 50B, the bridge die 50R (if present), and the dummy semiconductor features 120 (if present), such that the gap-fill dielectric 126 buries or covers the dummy semiconductor features 120, the bridge die 50R, and/or the second integrated circuit dies 50B. Accordingly, the top surface of the gap-fill dielectric 126 may initially be above the back-sides of the dummy semiconductor features 120, the bridge die 50R, and/or the second integrated circuit dies 50B. Subsequently, surfaces of the gap-fill dielectric 126 may be leveled with the back-sides of the dummy semiconductor features 120 (e.g., the back surfaces of the semiconductor substrates 122), the bridge die 50R (e.g., the back surface of the semiconductor substrate 52R), and/or the second integrated circuit dies 50B (e.g., the inactive surfaces of the semiconductor substrates 52B), in a similar manner as previously described for FIGS. 4-5.

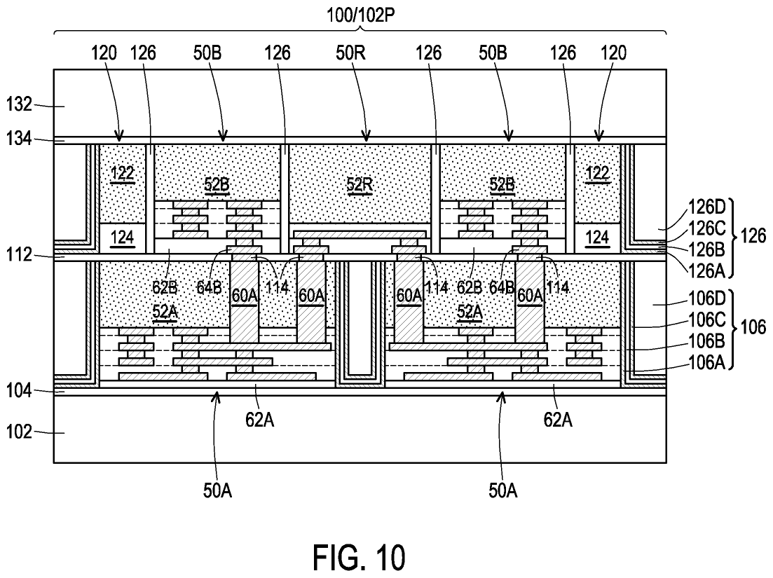

In FIG. 10, a support substrate 132 is attached to the gap-fill dielectric 126, the second integrated circuit dies 50B, the bridge die 50R (if present), and the dummy semiconductor features 120 (if present). The support substrate 132 may be a glass support substrate, a ceramic support substrate, a semiconductor substrate (e.g., a silicon substrate), a wafer (e.g., a silicon wafer), or the like. The support substrate 132 may provide structural support during subsequent processing steps and in the completed device. The support substrate 132 may be substantially free of any active or passive devices.

The support substrate 132 may be attached to the gap-fill dielectric 126, the second integrated circuit dies 50B, the bridge die 50R (if present), and the dummy semiconductor features 120 (if present) with one or more bonding layer(s) 134. The bonding layer(s) 134 are on a surface of the support substrate 132 and surfaces of the dummy semiconductor features 120, the bridge die 50R, and/or the second integrated circuit dies 50B. In some embodiments, the bonding layer(s) 134 include a release layer, such as an epoxy-based thermal-release material, which loses its adhesive property when heated, such as a light-to-heat-conversion (LTHC) release coating; an ultra-violet (UV) glue, which loses its adhesive property when exposed to UV light; or the like. In some embodiments, the bonding layer(s) 134 include an adhesive, such as a suitable epoxy, a die attach film (DAF), or the like. In some embodiments, the bonding layer(s) 134 include an oxide layer such as a layer of silicon oxide. The bonding layer(s) 134 may be applied to the back-sides of the dummy semiconductor features 120, the bridge die 50R, and/or the second integrated circuit dies 50B; may be applied over the surface of the support substrate 132; and/or the like.

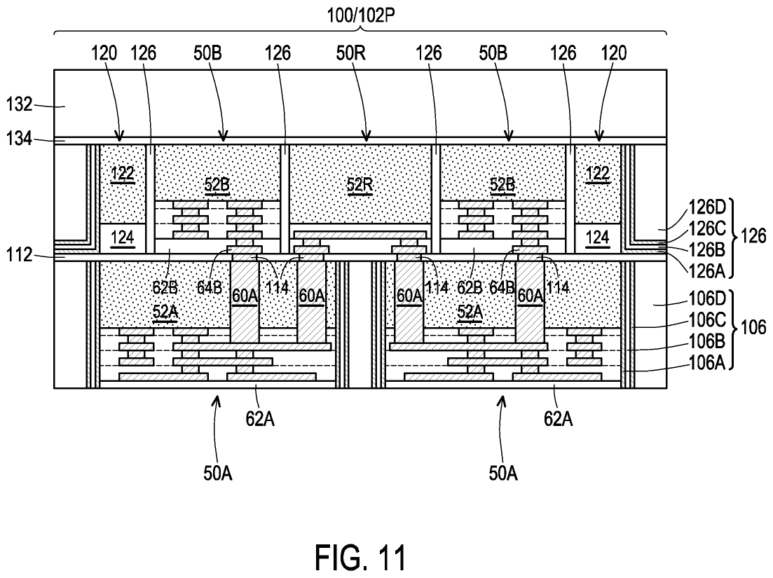

In FIG. 11, a carrier substrate de-bonding is performed to detach (or “de-bond”) the carrier substrate 102 from the first integrated circuit dies 50A. The gap-filling dielectric 106 and the front-sides of the first integrated circuit dies 50A are thus exposed. In some embodiments where the bonding layer(s) 104 include an oxide layer, the de-bonding includes applying a removal process, such as a grinding process, to the carrier substrate 102 and the bonding layer(s) 104. The removal process may also remove some portions of the gap-filling dielectric 106, such that each of the first liner 106A, the second liner 106B, the third liner 106C, and the main filler 106D are exposed. In some embodiments where the bonding layer(s) 104 include a release layer, the de-bonding includes projecting a light such as a laser light or a UV light on the bonding layer(s) 104 so that the bonding layer(s) 104 decomposes under the heat of the light and the carrier substrate 102 can be removed. The structure is then flipped over and placed on a tape (not separately illustrated).

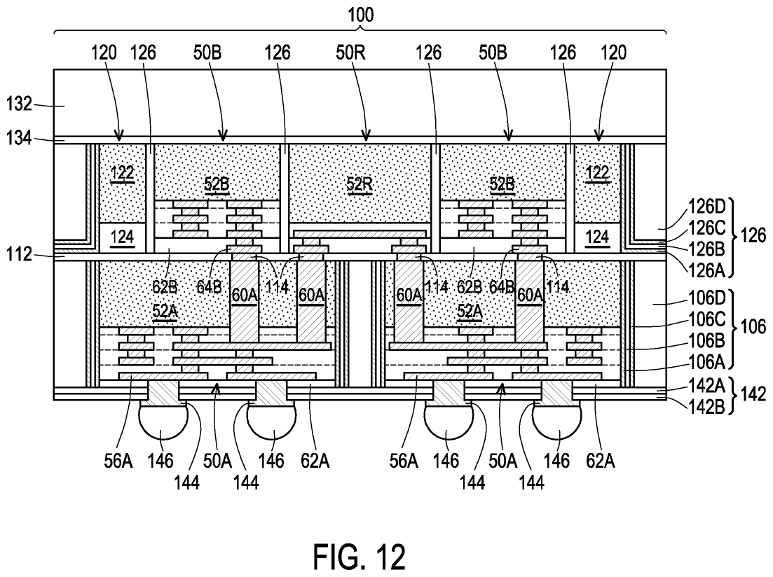

In FIG. 12, a singulation process is performed along scribe line regions, e.g., between the device region 102D and adjacent device regions (not separately illustrated). The singulation process may include performing a sawing process, a laser cutting process, or the like. The singulation process separates the device region 102D from the adjacent device regions. The resulting, singulated die structure 100 is from the device region 102D. After the singulation process, the gap-fill dielectric 106, the dielectric layer 112, the gap-fill dielectric 126, and the support substrate 132 are laterally coterminous.

The die structure 100 is a component that may be subsequently implemented in an integrated circuit package. The integrated circuit dies 50 of the die structure 100 may be heterogeneous dies. Packaging the die structure 100 in lieu of or in addition to packaging dies individually may allow heterogeneous dies to be integrated with a smaller footprint. In some embodiments, an integrated circuit package is formed by encapsulating the die structure 100 and forming redistribution lines on the encapsulant to fan-out connections from the die structure 100. In some embodiments, an integrated circuit package is formed by attaching the die structure 100 to an additional component, such as an interposer, a package substrate, or the like.

The die structure 100 may include additional features for attaching the die structure 100 to an additional component. In this embodiment, the die structure 100 further includes one or more passivation layer(s) 142, die connectors 144, and conductive connectors 146. The conductive connectors 146 may be used to connect the die structure 100 (e.g., the die connectors 144) to the additional component. The passivation layer(s) 142, the die connectors 144, and the conductive connectors 146 may be formed before or after the die structure 100 is singulated.

The passivation layer(s) 142 may be formed on the front-sides of the first integrated circuit dies 50A and the gap-filling dielectric 106 that were exposed by removal of the carrier substrate 102 (see FIG. 10). The passivation layer(s) 142 may be formed of one or more suitable dielectric materials such as silicon oxynitride, silicon nitride, low-k dielectrics such as carbon doped oxides, extremely low-k dielectrics such as porous carbon doped silicon oxide, or the like; a polymer such as polyimide, solder resist, polybenzoxazole (PBO), a benzocyclobutene (BCB) based polymer, molding compound, or the like; a combination thereof; or the like. The passivation layer(s) 142 may be formed by chemical vapor deposition (CVD), spin coating, lamination, the like, or a combination thereof. In some embodiments, the passivation layer(s) 142 include a first passivation layer 142A formed of an oxide and a second passivation layer 142B formed of a nitride.

The die connectors 144 may be formed through the passivation layer(s) 142 and the dielectric layers 62A of the first integrated circuit dies 50A to contact the upper metallization pattern 56A of the first integrated circuit dies 50A. The die connectors 144 may include conductive pillars, pads, or the like, to which external connections can be made. The die connectors 144 can be formed of a conductive material, such as a metal, such as copper, aluminum, or the like, which can be formed by, for example, plating, or the like. As an example to form the die connectors 144, the passivation layer(s) 142 and the dielectric layers 62A are patterned utilizing photolithography and etching techniques to form openings corresponding to the desired pattern of the die connectors 144. The openings may then be filled with a conductive material (previously described) to form the die connectors 144 in the openings.

The conductive connectors 146 may be formed on the die connectors 144. The conductive connectors 146 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 146 may include a conductive material such as solder, copper, aluminum, gold, nickel, silver, palladium, tin, the like, or a combination thereof. In some embodiments, the conductive connectors 146 are formed by initially forming a layer of a reflowable material (e.g., solder) through evaporation, electroplating, printing, solder transfer, ball placement, or the like. Once a layer of solder has been formed on the structure, a reflow may be performed in order to shape the material into the desired bump shapes.

FIG. 13 is a cross-sectional view of a die structure 100, in accordance with some embodiments. This embodiment is similar to the embodiment of FIG. 12, except the die structure 100 includes more than two layers of integrated circuit dies 50, such as three layers of integrated circuit dies 50 (including first integrated circuit dies 50A, second integrated circuit dies 50B, and third integrated circuit dies 50C). Conductive vias 60 may be formed in appropriate ones of the integrated circuit dies 50 (e.g., integrated circuit dies 50A, 50B) to facilitate connection to other ones of the integrated circuit dies 50 (e.g., integrated circuit dies 50B, 50C).

A dielectric layer 152 is formed on the gap-fill dielectric 126, the second integrated circuit dies 50B, the bridge die 50R (if present), and the dummy semiconductor features 120 (if present). The dielectric layer 152 may be formed in a similar manner as the dielectric layer 112. Bond pads 154 are formed in the dielectric layer 152. The bond pads 154 may be formed in a similar manner as the bond pads 114. The bond pads 154 extend through the dielectric layer 152 to contact the conductive vias 60B of the second integrated circuit dies 50B. Each bond pad 154 is smaller (e.g., narrower) than the underlying conductive via 60B.

Third integrated circuit dies 50C are attached to the dielectric layer 152 and the bond pads 154, such that the front-sides of the third integrated circuit dies 50C face the back-sides of the second integrated circuit dies 50B. The third integrated circuit dies 50C may be attached to the dielectric layer 152 and the bond pads 154 using a similar bonding process as that used to attach the second integrated circuit dies 50B to the dielectric layer 112 and the bond pads 114. Optionally, dummy semiconductor features 120 and/or a bridge die 50R are attached to the dielectric layer 152 and the bond pads 154. A gap-fill dielectric 156 is formed around the third integrated circuit dies 50C, the bridge die 50R (if present), and the dummy semiconductor features 120 (if present). The gap-fill dielectric 156 is a dielectric filler (or dielectric feature) that fills the gaps between the dummy semiconductor features 120, the bridge die 50R, and/or the third integrated circuit dies 50C. The gap-filling dielectric 156 may be formed in a similar manner as the gap-filling dielectric 126 of FIG. 9. Specifically, the gap-fill dielectric 156 may have a nitride-oxide-nitride-oxide (NONO) structure, in which the first liner 156A and the third liner 156C are formed of nitrides (previously described), and in which the second liner 156B and the main filler 156D are formed of oxides (previously described). The support substrate 132 is attached to the gap-fill dielectric 156, the third integrated circuit dies 50C, the bridge die 50R (if present), and the dummy semiconductor features 120 (if present).

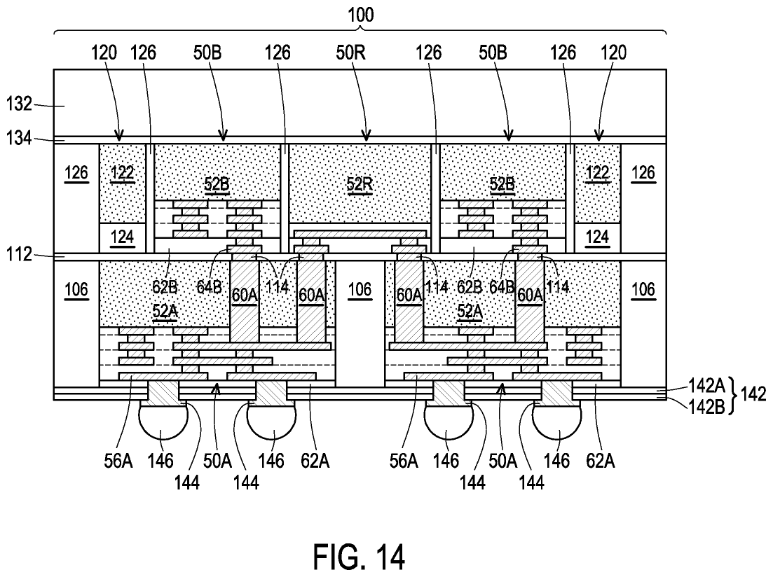

FIG. 14 is a cross-sectional view of a die structure 100, in accordance with some embodiments. This embodiment is similar to the embodiment of FIG. 12, except the gap-fill dielectric 106 and/or the gap-fill dielectric 126 includes an epoxy material in lieu of a nitride-oxide-nitride-oxide (NONO) structure. The epoxy material may be a molding compound, an underfill, or the like. When a molding compound is used, it may be applied by compression molding, transfer molding, or the like. When an underfill is used, it may be applied by a capillary flow process, a deposition process, or the like.

FIG. 15 is a cross-sectional view of a die structure 100, in accordance with some embodiments. This embodiment is similar to the embodiment of FIG. 12, except the bond pads 114 contact the conductive vias 60A with a one-to-many correspondence and also contact the die connectors 64B with a one-to-many correspondence. Specifically, a plurality of bond pads 114 contact each conductive via 60A and contact each die connector 64B. A width of each bond pad 114 may be less than half a width of the underlying conductive via 60A and of the overlying die connector 64B.

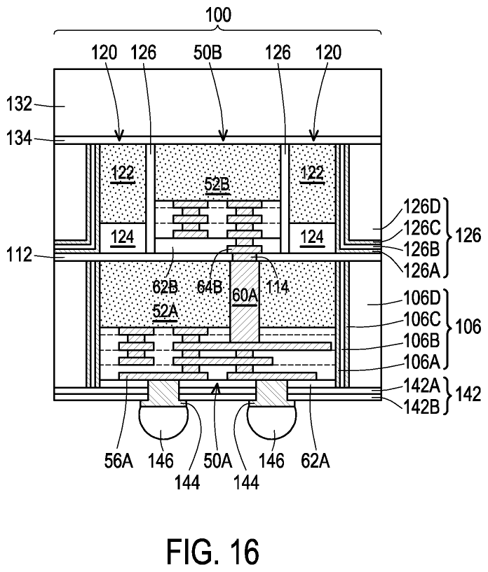

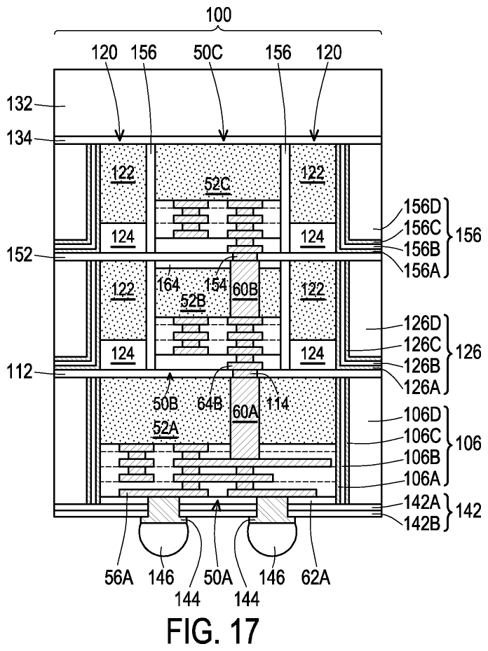

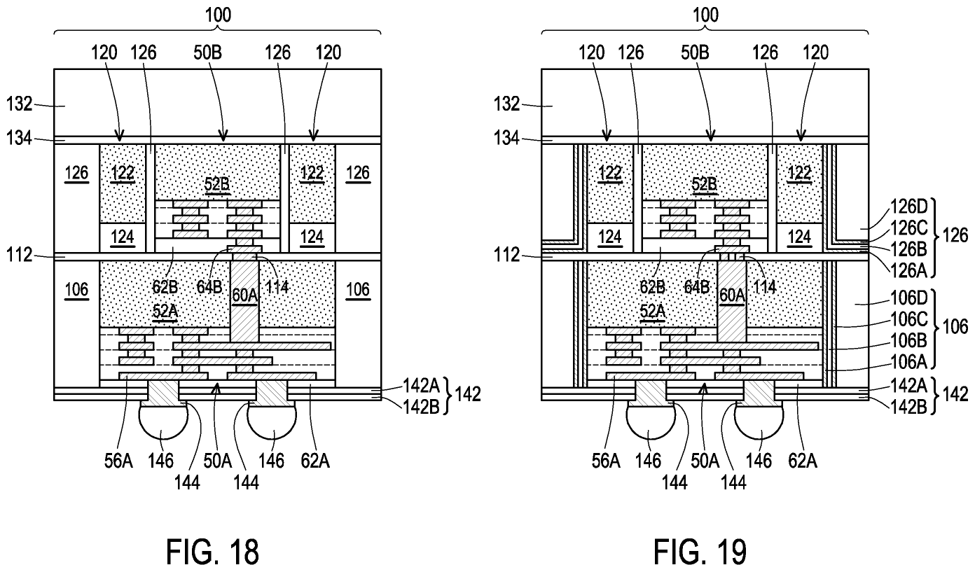

FIGS. 16-19 are cross-sectional views of die structures 100, in accordance with some embodiments. These embodiments are similar to the embodiments of FIG. 12-15, respectively, except the bridge die 50R is omitted. Additionally, the die structures 100 each only include one first integrated circuit die 50A and one second integrated circuit die 50B.

Embodiments may achieve advantages. Forming the bond pads 114 on the conductive vias 60A allows vertical connections to the second integrated circuit dies 50B to be achieved without recessing the semiconductor substrates 52A. When the gap-fill dielectric 106 has a nitride-oxide-nitride-oxide structure, omitting the recessing of the semiconductor substrates 52A may avoid etching of the first liner 106A and the third liner 106C (e.g., nitrides), thereby reducing pin hole defects in the die structure 100. Reducing pin hole defects can improve the yield and reliability of the die structure 100. Forming the bond pads 114 smaller than the conductive vias 60A helps reduce the risk of the bond pads 114 contacting the semiconductor substrates 52A. Shorting of the devices of the semiconductor substrates 52A may thus be avoided.

Other techniques may be used to reduce pin hole defects in the die structure 100. As subsequently described in greater detail, the gap-fill dielectric 106 may be formed in a manner that allows the semiconductor substrates 52A to be recessed while avoiding damage to the liner(s) of the gap-fill dielectric 106. Pin hole defects in the die structure 100 may thus be reduced, even if the semiconductor substrates 52A are recessed so that the conductive vias 60A protrude from the inactive surfaces of the semiconductor substrates 52A.

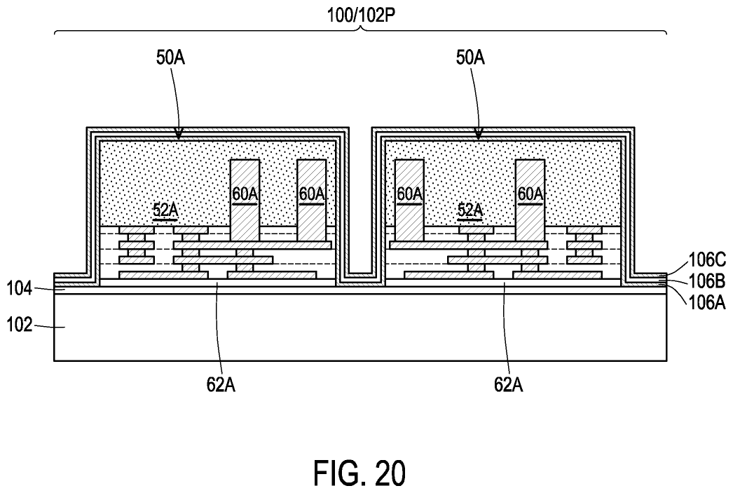

FIGS. 20-26 are cross-sectional views of intermediate stages in the manufacturing of a die structure 100, in accordance with some embodiments. In this embodiment, the main filler 106D is formed to cover the third liner 106C. As such, the main filler 106D may protect the third liner 106C during recessing of the semiconductor substrates 52A.

In FIG. 20, the structure of FIG. 2 is obtained. The liner layer(s) of the gap-fill dielectric 106, e.g., the first liner 106A, the second liner 106B, and the third liner 106C, are then formed around the first integrated circuit dies 50A and over the carrier substrate 102. The first liner 106A, the second liner 106B, and the third liner 106C may be formed in a similar manner as previously described for FIG. 3.

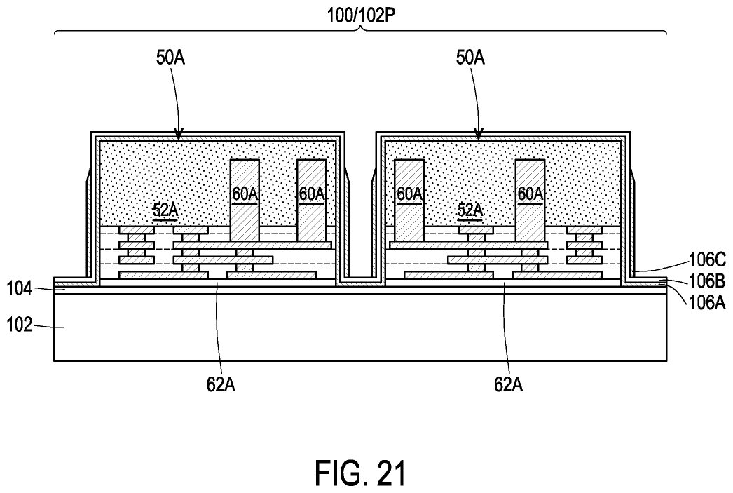

In FIG. 21, the third liner 106C is patterned such that the third liner 106C is recessed. The third liner 106C may be patterned by etching the third liner 106C to remove horizontal portions of the third liner 106C. Any acceptable etch process, such as a dry etch, a wet etch, the like, or a combination thereof, may be performed to pattern the third liner 106C. The etching may be anisotropic. The second liner 106B may be used as an etch stop layer when etching the third liner 106C, such that the horizontal portions of the second liner 106B are exposed by the patterning of the third liner 106C. The third liner 106C, when etched, has vertical portions left on the sidewalls of the second liner 106B. The remaining vertical portions of the third liner 106C are along the edges of the first integrated circuit dies 50A. As a result, the gap-fill dielectric 106 still has a nitride-oxide-nitride-oxide structure along the edges of the first integrated circuit dies 50A.

In this embodiment, the third liner 106C is patterned such that the top surfaces of the third liner 106C are inclined top surfaces. Specifically, each top surface of the third liner 106C forms an acute angle with an inner sidewall of the third liner 106C and forms an obtuse angle with an outer sidewall of the third liner 106C. In another embodiment (not separately illustrated), the top surfaces of the third liner 106C are flat top surfaces.

As subsequently described in greater detail, the semiconductor substrates 52A will be recessed so that the conductive vias 60A protrude from the inactive surfaces of the semiconductor substrates 52A. The third liner 106C is patterned such that the top surfaces of the third liner 106C are beneath the top surfaces of the conductive vias 60A. As a result, when the semiconductor substrates 52A is subsequently recessed to expose the conductive vias 60A, the third liner 106C is not etched.

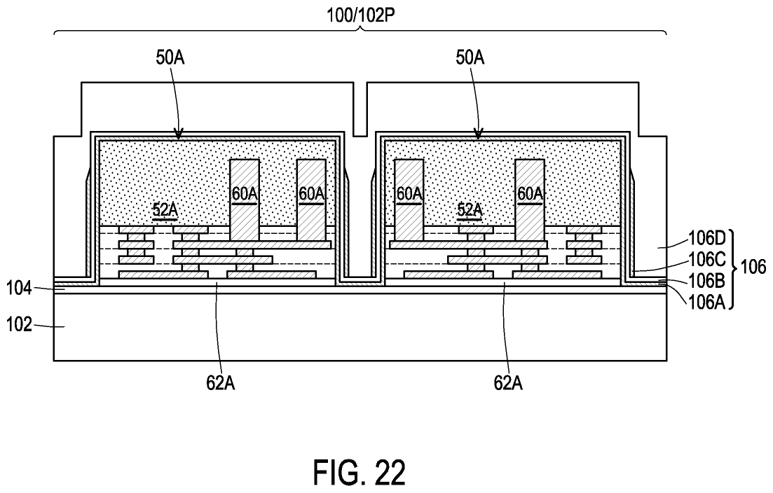

In FIG. 22, the main layer of the gap-fill dielectric 106, e.g., the main filler 106D, is formed on the liner layer(s) of the gap-fill dielectric 106, e.g., the third liner 106C and the second liner 106B. The main filler 106D may be formed in a similar manner as previously described for FIG. 3.

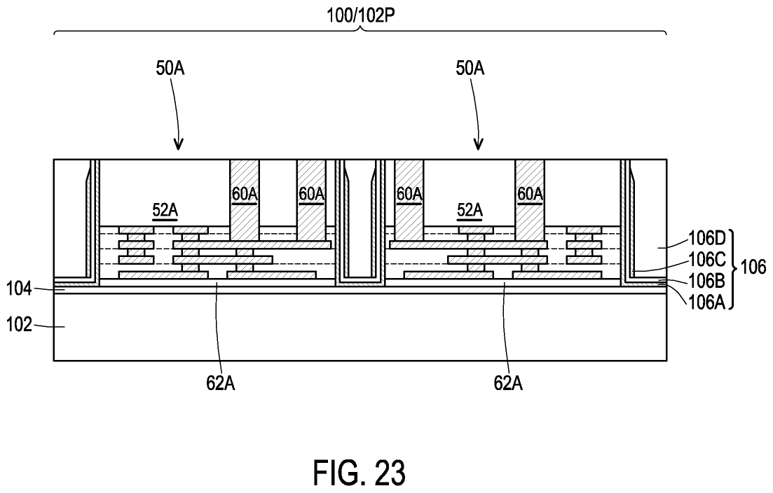

In FIG. 23, a removal process is performed to level surfaces of the gap-fill dielectric 106 with the back-sides of the first integrated circuit dies 50A (e.g., the inactive surfaces of the semiconductor substrates 52A). The removal process may be performed in a similar manner as previously described for FIG. 5. The removal process may include removing portions of the gap-fill dielectric 106 above the first integrated circuit dies 50A by etching, in a similar manner as previously described for FIG. 4. Additionally, the semiconductor substrates 52A may be thinned to expose the conductive vias 60A, in a similar manner as previously described for FIG. 5. After the removal process, the third liner 106C remains buried and covered by the main filler 106D. The main filler 106D extends along the outer sidewalls and the top surfaces of the third liner 106C.

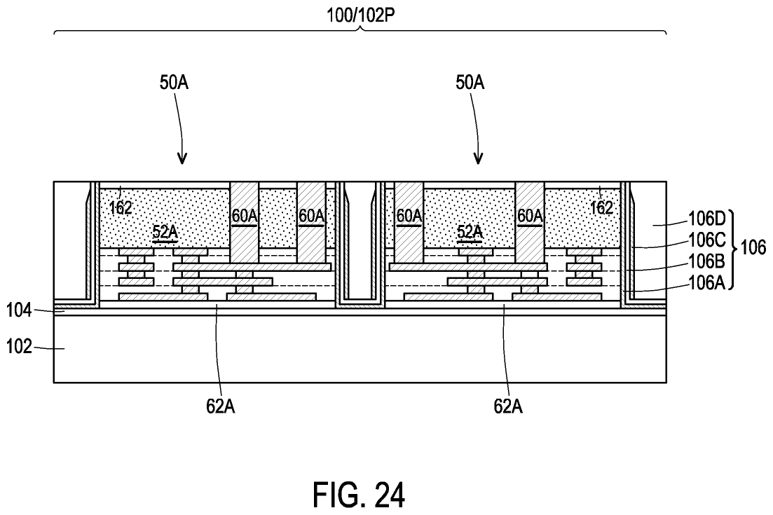

In FIG. 24, isolation layers 162 are optionally formed around the conductive vias 60A. The isolation layers 162 can help electrically isolate the conductive vias 60A from one another, thus avoiding shorting, and can also be utilized in a subsequent bonding process. Additionally, the isolation layers 162 help protect the inactive surface of the semiconductor substrates 52A. As an example to form the isolation layers 162, the semiconductor substrates 52A are recessed so the conductive vias 60A protrude from the inactive surfaces of the semiconductor substrates 52A. The recessing exposes portions of the sidewalls of the conductive vias 60A. The recessing may be by an etching process, such as a dry etch, a wet etch, or combinations thereof. A dielectric material can then be formed in the recess. The dielectric material can be an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like. Other suitable dielectric materials, such as a low temperature polyimide material, PBO, an encapsulant, combinations of these, or the like may also be utilized. A planarization process, such as a CMP, grinding, or etch-back, can be performed to remove excess portions of the dielectric material over the conductive vias 60A. The remaining portions of the dielectric material in the recesses form the isolation layers 162. The isolation layers 162 laterally surround portions of the sidewalls of the respective conductive vias 60A.

As previously noted, the third liner 106C is recessed so that it is buried and covered by the main filler 106D. The top surfaces of the third liner 106C are beneath the inactive surfaces of the semiconductor substrates 52A. The top surfaces of the first liner 106A, the second liner 106B, and the main filler 106D are above the inactive surfaces of the semiconductor substrates 52A, and are substantially coplanar (within process variations) with the top surfaces of the conductive vias 60A and the isolation layers 162. The third liner 106C is thus not etched during the recessing of the semiconductor substrates 52A, thereby reducing pin hole defects in the die structure 100. Reducing pin hole defects can improve the yield and reliability of the die structure 100.

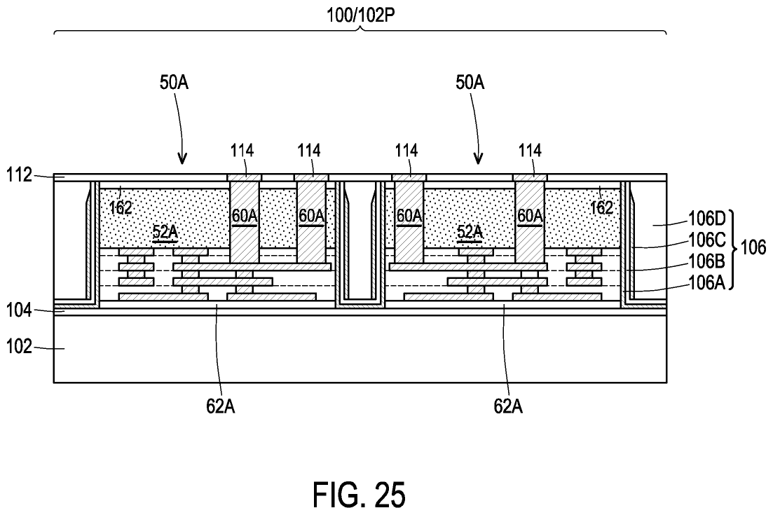

In FIG. 25, a dielectric layer 112 is formed on the gap-fill dielectric 106 and the first integrated circuit dies 50A. The dielectric layer 112 may be formed in a similar manner as previously described for FIG. 6. Bond pads 114 are formed in the dielectric layer 112. The bond pads 114 may be formed in a similar manner as previously described for FIG. 6, except in this embodiment, each bond pad 114 may be larger (e.g., wider) than the underlying conductive via 60A. More specifically, the critical dimension (e.g., width) of the bond pads 114 may be greater than the critical dimension (e.g., width) of the conductive vias 60A. In some embodiments, the critical dimension of the bond pads 114 is in the range of 1 μm to 8 μm and the critical dimension of the conductive vias 60A is in the range of 0.5 μm to 6 μm.

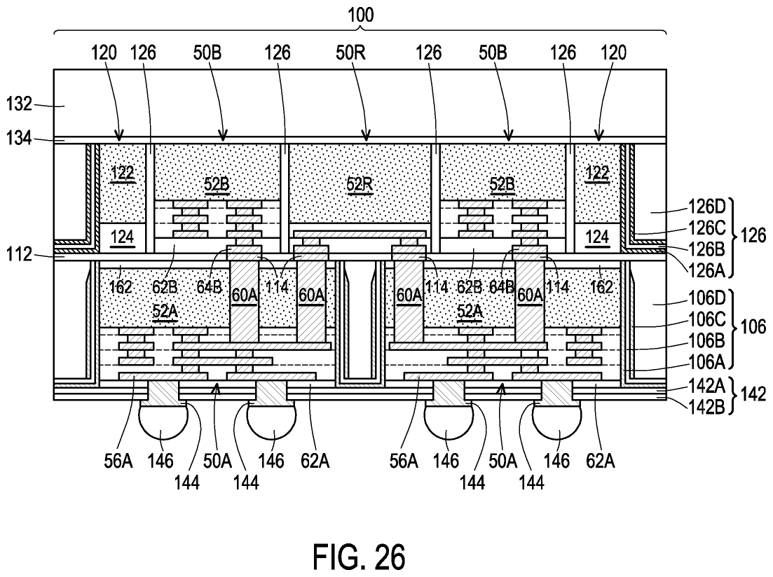

In FIG. 26, appropriate processing as previously described for FIGS. 7-12 is performed to complete the die structure 100. The gap-fill dielectric 126 is formed in a similar manner as previously described for FIG. 9. No recessing of the semiconductor substrates 52B is performed to expose through-substrate vias. Accordingly, the third liner 126C of the gap-fill dielectric 126 may not be recessed. As such, the top surfaces of the first liner 126A, the second liner 126B, the third liner 126C, and the main filler 126D may be substantially coplanar (within process variations).

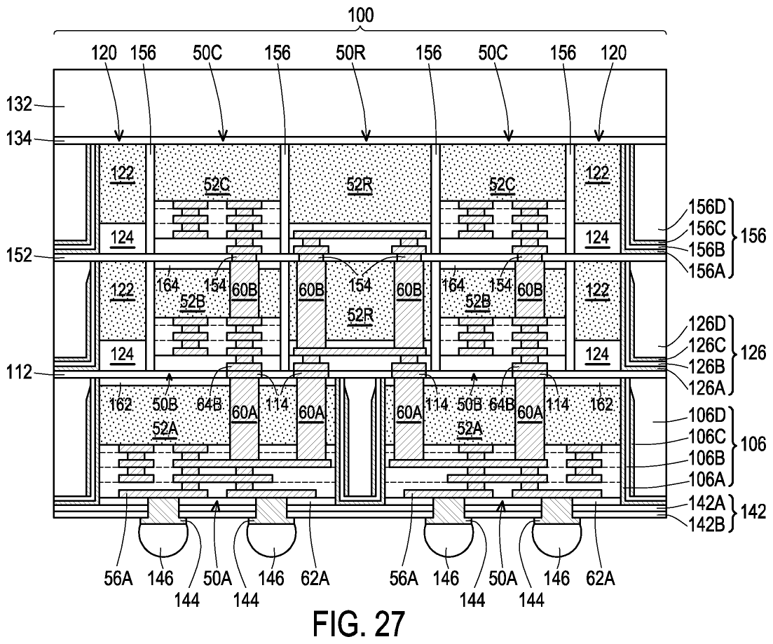

FIG. 27 is a cross-sectional view of a die structure 100, in accordance with some embodiments. This embodiment is similar to the embodiment of FIG. 26, except the die structure 100 includes more than two layers of integrated circuit dies 50, such as three layers of integrated circuit dies 50 (including first integrated circuit dies 50A, second integrated circuit dies 50B, and third integrated circuit dies 50C), in a similar manner as the embodiment of FIG. 13.

The semiconductor substrates 52B are recessed so the conductive vias 60B protrude from the inactive surfaces of the semiconductor substrates 52B. Isolation layers 164 are optionally formed around the conductive vias 60B of the second integrated circuit dies 50B, in a similar manner as the isolation layers 162 described for FIG. 24. The gap-fill dielectric 126 is formed in a similar manner as previously described for the gap-fill dielectric 106 of FIGS. 20-23. Accordingly, the third liner 126C is recessed so that it is buried and covered by the main filler 126D. The third liner 126C is thus not etched during the recessing of the semiconductor substrates 52B, thereby reducing pin hole defects in the die structure 100.

A gap-fill dielectric 156 is formed around the third integrated circuit dies 50C, in a similar manner as previously described for the gap-fill dielectric 106 of FIG. 9. No recessing of the semiconductor substrates 52C is performed to expose through-substrate vias. Accordingly, the third liner 156C of the gap-fill dielectric 156 may not be recessed.

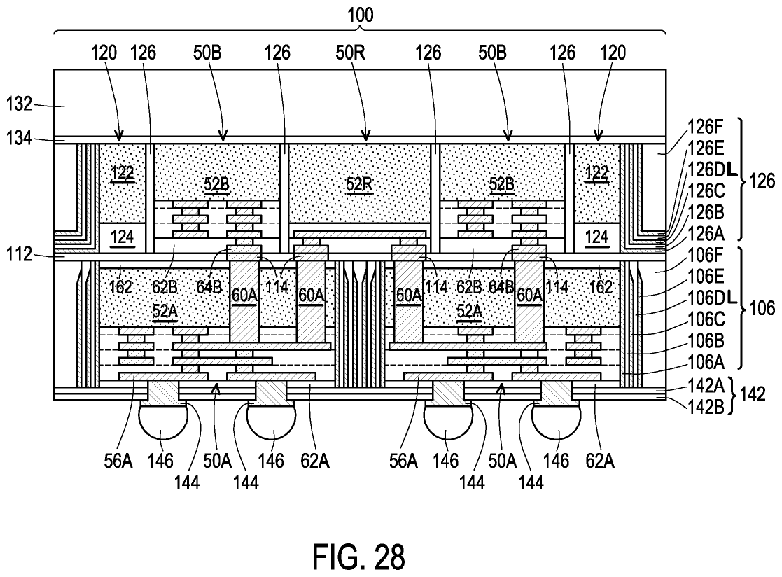

FIG. 28 is a cross-sectional view of a die structure 100, in accordance with some embodiments. This embodiment is similar to the embodiment of FIG. 26, except the gap-fill dielectric 106 includes a first liner 106A, a second liner 106B, a third liner 106C, a fourth liner 106D, a fifth liner 106E, and a main filler 106F. The fifth liner 106E may be formed in a similar manner as the third liner 106C, e.g., recessed so that it is buried and covered by the main filler 106DF. Additionally, the gap-fill dielectric 126 includes a first liner 126A, a second liner 126B, a third liner 126C, a fourth liner 126D, a fifth liner 126E, and a main filler 126F.

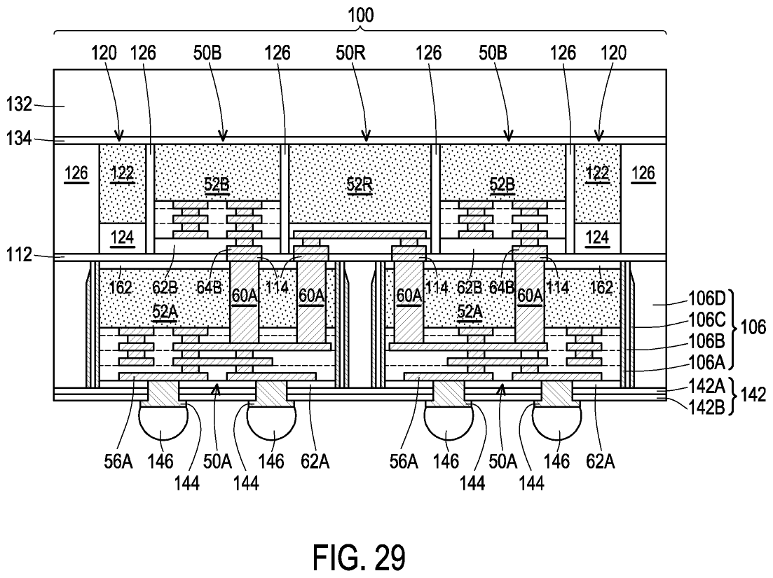

FIG. 29 is a cross-sectional view of a die structure 100, in accordance with some embodiments. This embodiment is similar to the embodiment of FIG. 26, except the gap-fill dielectric 126 includes an epoxy material in lieu of a nitride-oxide-nitride-oxide (NONO) structure, in a similar manner as the embodiment of FIG. 14.

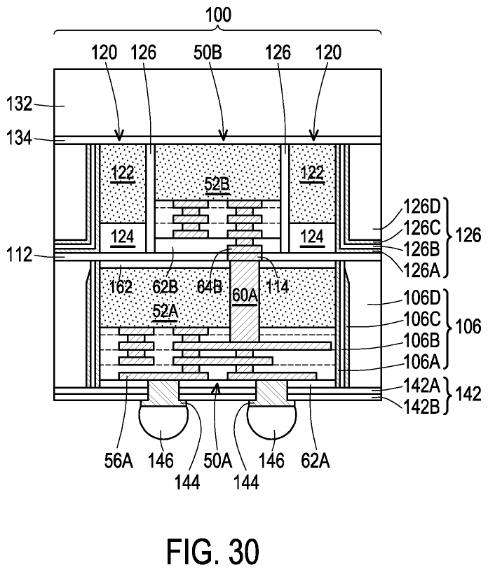

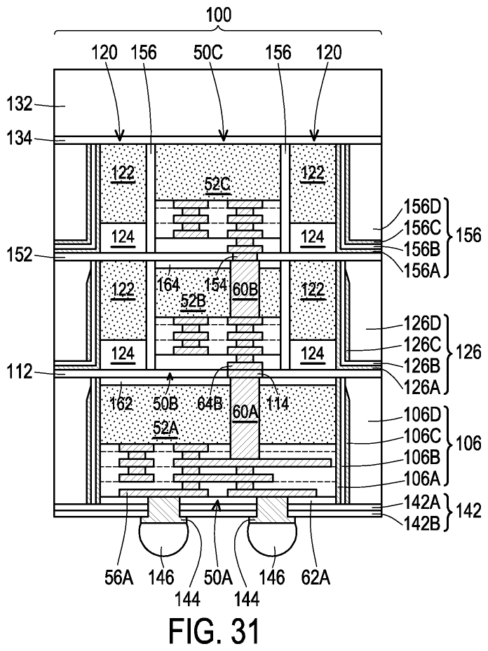

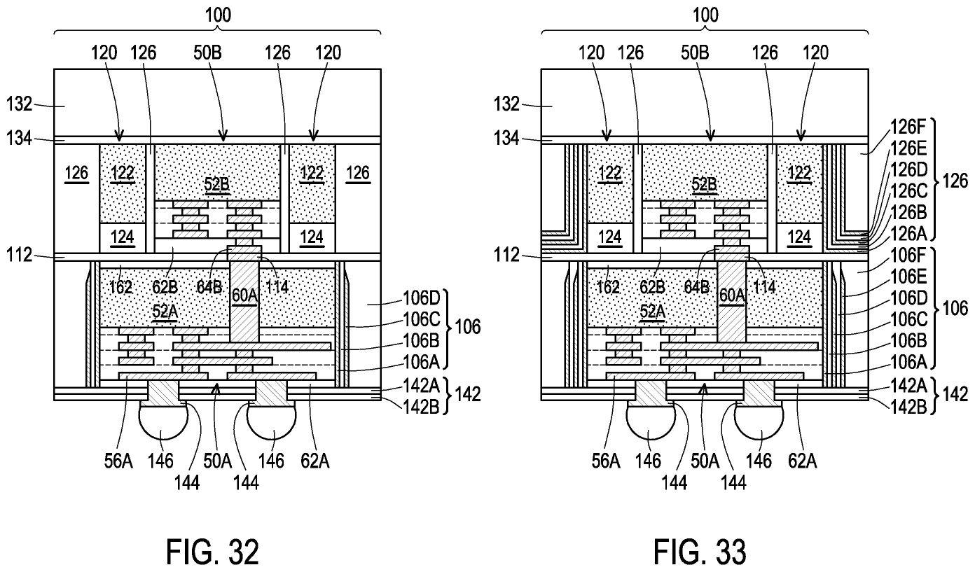

FIGS. 30-33 are cross-sectional views of die structures 100, in accordance with some embodiments. These embodiments are similar to the embodiments of FIG. 26-29, respectively, except the bridge die 50R is omitted. Additionally, the die structures 100 each only include one first integrated circuit die 50A and one second integrated circuit die 50B.

In an embodiment, a device includes: a first integrated circuit die comprising a semiconductor substrate and a first through-substrate via; a gap-fill dielectric around the first integrated circuit die, a surface of the gap-fill dielectric being substantially coplanar with an inactive surface of the semiconductor substrate and with a surface of the first through-substrate via; a dielectric layer on the surface of the gap-fill dielectric and the inactive surface of the semiconductor substrate; a first bond pad extending through the dielectric layer to contact the surface of the first through-substrate via, a width of the first bond pad being less than a width of the first through-substrate via; and a second integrated circuit die comprising a die connector bonded to the first bond pad. In some embodiments of the device, the first bond pad contacts the first through-substrate via with a one-to-one correspondence. In some embodiments, the device further comprises: a second bond pad extending through the dielectric layer to contact the surface of the first through-substrate via, the first bond pad and the second bond pad contacting the first through-substrate via with a one-to-many correspondence. In some embodiments of the device, a width of the first bond pad is greater than half the width of the first through-substrate via. In some embodiments of the device, a width of the first bond pad is less than half the width of the first through-substrate via. In some embodiments of the device, the first integrated circuit die further comprises a second through-substrate via, the device further comprising: a second bond pad extending through the dielectric layer to contact the second through-substrate via, a width of the second bond pad being less than a width of the second through-substrate via; and a bridge die comprising a second die connector bonded to the second bond pad. In some embodiments of the device, the gap-fill dielectric comprises a nitride-oxide-nitride-oxide structure. In some embodiments of the device, the gap-fill dielectric comprises an epoxy material.

In an embodiment, a device includes: a first integrated circuit die comprising a semiconductor substrate and a through-substrate via, the through-substrate via protruding from a surface of the semiconductor substrate; a first dielectric feature around the first integrated circuit die, the first dielectric feature comprising: a first nitride liner on a sidewall of the first integrated circuit die; a first oxide liner on the first nitride liner; a second nitride liner on the first oxide liner, a top surface of the second nitride liner being disposed below the surface of the semiconductor substrate; and a first oxide filler on the second nitride liner, wherein a top surface of the first oxide filler, a top surface of the first oxide liner, and a top surface of the first nitride liner are disposed above the surface of the semiconductor substrate. In some embodiments, the device further comprises: an isolation layer around the through-substrate via, a top surface of the isolation layer being substantially coplanar with the top surface of the first oxide filler, the top surface of the first oxide liner, and the top surface of the first nitride liner; a dielectric layer on the isolation layer and the first dielectric feature; a bond pad extending through the dielectric layer to contact the through-substrate via, a width of the through-substrate via being less than a width of the bond pad; and a second integrated circuit die comprising a die connector bonded to the bond pad. In some embodiments, the device further comprises: a second dielectric feature around the second integrated circuit die, the second dielectric feature comprising: a third nitride liner on a sidewall of the second integrated circuit die; a second oxide liner on the third nitride liner; a fourth nitride liner on the second oxide liner; and a second oxide filler on the fourth nitride liner, wherein a top surface of the second oxide filler, a top surface of the fourth nitride liner, a top surface of the second oxide liner, and a top surface of the third nitride liner are substantially coplanar. In some embodiments, the device further comprises: a second dielectric feature around the second integrated circuit die, the second dielectric feature comprising an epoxy material. In some embodiments of the device, the top surface of the second nitride liner is an inclined top surface. In some embodiments of the device, the top surface of the second nitride liner is a flat top surface.

In an embodiment, a method includes: forming a gap-fill dielectric around a first integrated circuit die, the first integrated circuit die comprising a semiconductor substrate and a through-substrate via; planarizing the gap-fill dielectric until the gap-fill dielectric, the semiconductor substrate, and the through-substrate via have top surfaces that are substantially coplanar; depositing a first dielectric layer on the top surfaces of the gap-fill dielectric, the semiconductor substrate, and the through-substrate via; forming a bond pad in the first dielectric layer, the bond pad extending through the first dielectric layer to contact the top surface of the through-substrate via; and bonding a second integrated circuit die to the bond pad and the first dielectric layer. In some embodiments of the method, the second integrated circuit die comprises a second dielectric layer and a die connector, and bonding the second integrated circuit die to the bond pad and the first dielectric layer comprises: pressing the second dielectric layer against the first dielectric layer; annealing the second dielectric layer and the first dielectric layer to form covalent bonds between a material of the second dielectric layer and a material of the first dielectric layer; and annealing the die connector and the bond pad to intermingle a material of the die connector and a material of the bond pad. In some embodiments of the method, a width of the bond pad is greater than half a width of the through-substrate via. In some embodiments of the method, a width of the bond pad is less than half a width of the through-substrate via. In some embodiments of the method, forming the gap-fill dielectric comprises forming a oxide-nitride-oxide structure around the first integrated circuit die. In some embodiments of the method, forming the gap-fill dielectric comprises forming an epoxy material around the first integrated circuit die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a first integrated circuit die comprising a semiconductor substrate and a first through-substrate via;
a gap-fill dielectric around the first integrated circuit die, a surface of the gap-fill dielectric being substantially coplanar with an inactive surface of the semiconductor substrate and with a surface of the first through-substrate via;
a dielectric layer on the surface of the gap-fill dielectric and the inactive surface of the semiconductor substrate;
a first bond pad extending through the dielectric layer to contact the surface of the first through-substrate via, a width of the first bond pad being less than a width of the first through-substrate via; and
a second integrated circuit die comprising a die connector bonded to the first bond pad.

2. The device of claim 1, wherein the first bond pad contacts the first through-substrate via with a one-to-one correspondence.

3. The device of claim 1 further comprising:
a second bond pad extending through the dielectric layer to contact the surface of the first through-substrate via, the first bond pad and the second bond pad contacting the first through-substrate via with a one-to-many correspondence.

4. The device of claim 1, wherein the width of the first bond pad is greater than half the width of the first through-substrate via.

5. The device of claim 1, wherein the width of the first bond pad is less than half the width of the first through-substrate via.

6. The device of claim 1, wherein the first integrated circuit die further comprises a second through-substrate via, the device further comprising:
a second bond pad extending through the dielectric layer to contact the second through-substrate via, a width of the second bond pad being less than a width of the second through-substrate via; and
a bridge die comprising a second die connector bonded to the second bond pad.

7. The device of claim 1, wherein the gap-fill dielectric comprises a nitride-oxide-nitride-oxide structure.

8. The device of claim 1, wherein the gap-fill dielectric comprises an epoxy material.

9. A device comprising:
a first integrated circuit die comprising a semiconductor substrate and a through-substrate via, the through-substrate via protruding from a surface of the semiconductor substrate;
a first dielectric feature around the first integrated circuit die, the first dielectric feature comprising:
a first nitride liner on a sidewall of the first integrated circuit die;
a first oxide liner on the first nitride liner;
a second nitride liner on the first oxide liner, a top surface of the second nitride liner being disposed below the surface of the semiconductor substrate; and
a first oxide filler on the second nitride liner, wherein a top surface of the first oxide filler, a top surface of the first oxide liner, and a top surface of the first nitride liner are disposed above the surface of the semiconductor substrate.

10. The device of claim 9 further comprising:
an isolation layer around the through-substrate via, a top surface of the isolation layer being substantially coplanar with the top surface of the first oxide filler, the top surface of the first oxide liner, and the top surface of the first nitride liner;
a dielectric layer on the isolation layer and the first dielectric feature;
a bond pad extending through the dielectric layer to contact the through-substrate via, a width of the through-substrate via being less than a width of the bond pad; and
a second integrated circuit die comprising a die connector bonded to the bond pad.

11. The device of claim 10 further comprising:
a second dielectric feature around the second integrated circuit die, the second dielectric feature comprising:
a third nitride liner on a sidewall of the second integrated circuit die;
a second oxide liner on the third nitride liner;
a fourth nitride liner on the second oxide liner; and
a second oxide filler on the fourth nitride liner, wherein a top surface of the second oxide filler, a top surface of the fourth nitride liner, a top surface of the second oxide liner, and a top surface of the third nitride liner are substantially coplanar.

12. The device of claim 10 further comprising:
a second dielectric feature around the second integrated circuit die, the second dielectric feature comprising an epoxy material.

13. The device of claim 9, wherein the top surface of the second nitride liner is an inclined top surface.

14. The device of claim 9, wherein the top surface of the second nitride liner is a flat top surface.

15. A method comprising:
forming a gap-fill dielectric around a first integrated circuit die, the first integrated circuit die comprising a semiconductor substrate and a through-substrate via;
planarizing the gap-fill dielectric until the gap-fill dielectric, the semiconductor substrate, and the through-substrate via have top surfaces that are substantially coplanar;
depositing a first dielectric layer on the top surfaces of the gap-fill dielectric, the semiconductor substrate, and the through-substrate via;
forming a bond pad in the first dielectric layer, the bond pad extending through the first dielectric layer to contact the top surface of the through-substrate via; and
bonding a second integrated circuit die to the bond pad and the first dielectric layer.

16. The method of claim 15, wherein the second integrated circuit die comprises a second dielectric layer and a die connector, and bonding the second integrated circuit die to the bond pad and the first dielectric layer comprises:
pressing the second dielectric layer against the first dielectric layer;
annealing the second dielectric layer and the first dielectric layer to form covalent bonds between a material of the second dielectric layer and a material of the first dielectric layer; and
annealing the die connector and the bond pad to intermingle a material of the die connector and a material of the bond pad.

17. The method of claim 15, wherein a width of the bond pad is greater than half a width of the through-substrate via.

18. The method of claim 15, wherein a width of the bond pad is less than half a width of the through-substrate via.

19. The method of claim 15, wherein forming the gap-fill dielectric comprises forming a nitride-oxide-nitride-oxide structure around the first integrated circuit die.

20. The method of claim 15, wherein forming the gap-fill dielectric comprises forming an epoxy material around the first integrated circuit die.
